(19) United States
(12) Patent Application Publication
(10) Pub. No.: US 2013/0168676 A1
(43) Pub. Date: Jul. 4, 2013

(54) Super-Junction Structure of Semiconductor Device and Method of Forming the Same

(71) Applicant: Yongseong KIM, Seoul (KR)

(72) Inventor: Yongseong KIM, Seoul (KR)

(21) Appl. No.: 13/536,828

(22) Filed: Jun. 28, 2012

(30) Foreign Application Priority Data
Dec. 30, 2011 (KR) 10-2011-0147259

(51) Int. Cl. H01L 29/16; H01L 21/20

(52) U.S. Cl. 257/49; 438/478; 257/E21.09; 257/E29.082

(57) ABSTRACT

A super-junction of a semiconductor device is formed by forming a polysilicon layer on a semiconductor substrate; patterning the polysilicon layer to form pillars for a super-junction structure; and growing an epitaxial layer between the pillars to form a continuous PN junction structure of the super-junction, which forms the super-junction structure more accurately. It is therefore possible to simplify the process for forming the super-junction without using a repetitive ion implantation process a trench process, thereby increasing productivity and device reliability.

### RELATED APPLICATIONS

This application claims the benefit of Korean Patent Application No. 10-2011-0147259, filed on Dec. 30, 2011, which is hereby incorporated by reference as if fully set forth herein.

### FIELD OF THE INVENTION

The present invention relates to a semiconductor device, and more particularly, relates to a super-junction structure of a semiconductor device with an accurate and/or more reliable super-junction structure and a method of forming such a device, including a simplified process for forming the super-junction structure to increase device productivity and reliability.

### BACKGROUND. OF THE INVENTION

A super-junction structure of a semiconductor device refers to a structure which includes alternating n-type and p-type conductive type drift layers. The alternating conductive type drift layers are used as a current path in the on-state of the semiconductor device, and are depleted in the off-state of the semiconductor device. In particular, the super-junction structure is widely used in a high-voltage semiconductor device.

FIGS. 1A and 1B are cross-sectional views of a semiconductor device having a vertical super-junction structure.

More specifically, FIG. 1A shows a vertical super-junction structure of a semiconductor device in which ion implantation and epitaxial layer growth are repetitively performed to form a P region having a desired depth in the semiconductor device; and FIG. 1B shows a vertical super-junction structure of a semiconductor device in which a trench is formed at a desired depth and P pillars are formed in an n-type semiconductor substrate, thereby forming a P region at a desired depth in the vertical semiconductor device.

As illustrated in FIGS. 1A and 1B, in the super-junction structure, an N⁺ drain electrode and/or drain layer is/are formed at lower part of a semiconductor substrate. An n-type epitaxial layer is grown to form an N⁻ drift layer. A gate insulating film and a gate electrode are deposited on a portion of the N⁻ drift layer. A source electrode is formed on the semiconductor substrate separate from the gate electrode. A P region doped with a p-type dopant, that is, a P RESURF layer is formed to extend from the lower part of the source electrode to a given depth of the N⁻ drift layer.

In a semiconductor device having a vertical super-junction structure, when the semiconductor device is turned on, a current flows in the vertical direction through the N⁻ drift layer. Applying a bias voltage extends a depletion region in the super-junction structure. Subsequently, most of the space occupied by the SF drift layer becomes the depletion region, thereby allowing a large amount of current to flow and increasing the breakdown voltage of the semiconductor device.

FIG. 2 is a view showing a semiconductor device having a lateral super-junction structure formed laterally on a semiconductor substrate. The operation principle is the same as in the vertical super-junction structure in FIGS. 1A and 1B.

When manufacturing a semiconductor device having a vertical or lateral super-junction structure, epitaxial layer growth and ion implantation processes may be sequentially and repetitively performed to form a p-type or n-type doped region to a desired depth in the semiconductor substrate. Alternatively, a super-junction structure may be formed by forming a trench in the semiconductor substrate to a desired depth through a trench-forming process, and forming an epitaxial layer in the trench having an opposite conductive type to that of the semiconductor substrate, thereby forming a p-type or n-type doped region having a desired depth in the semiconductor substrate.

However, in the method of forming the doped region through the repetition of epitaxial layer growth and ion implantation, it is difficult to accurately align the semiconductor substrate in the course of growing the epitaxial layer in a stepwise manner. In the method of forming the doped region using the trench process, it is difficult to accurately and/or reliably form the trench to a desired depth by etching the semiconductor substrate. Additionally, the trench process is costly due to the need for an expensive trench etching apparatus.

### SUMMARY OF THE INVENTION

in view of the above, the invention provides a super-junction structure of a semiconductor device with an accurate and/or reliable super-junction structure (e.g., a super-junction structure that is accurately located in a predetermined area of a substrate and that has precisely formed dimensions) and a method of forming such a device, including a simplified process for forming the super-junction structure to increase device productivity and reliability.

in one aspect, the invention relates to a method of forming a super-junction of a semiconductor device. The method includes:

forming a polysilicon layer on a semiconductor substrate;

patterning the polysilicon layer to form polysilicon pillars on the semiconductor substrate; and
growing an epitaxial layer having a height at least equal to the height of the polysilicon pillars on the semiconductor substrate, thereby forming a continuous PN junction structure for the super-junction.

Preferably, the polysilicon layer has a height corresponding to the height of the polysilicon pillars.

Preferably, the polysilicon layer has a conductivity type opposite to the conductivity type of the semiconductor substrate.

Preferably, the epitaxial layer has the same conductivity type as the semiconductor substrate.

In another aspect, the invention relates to a super-junction structure of a semiconductor device. The super-junction structure includes:

patterned polysilicon pillars on a semiconductor substrate; and

an epitaxial layer on the semiconductor substrate and between the pillars at a height equal to a height of the pillars, forming a continuous PN junction structure. For example, the continuous PN junction structure may be formed at the interface of the pillars with the epitaxial layer and the substrate.

Preferably, the polysilicon pillars have a height corresponding to the height of the pillars.

Preferably, the polysilicon pillars have a conductivity type opposite to the conductivity type of the semiconductor substrate.

Preferably, the epitaxial layer has the same conductivity type as the semiconductor substrate.

### BRIEF DESCRIPTION OF THE DRAWINGS

The objects, benefits, and features of the present invention discussed above will be further explained in the following description of various embodiments. The accompanying drawings illustrate embodiments of the invention and, along with the description, serve to explain the principles of the invention. In the drawings:

FIGS. 1A and 1F are cross-sectional views of a semiconductor device having a vertical super-junction structure consistent with the related art;

FIG. 2 is a view of a semiconductor device having a lateral super-junction structure of the related art;

FIG. 3 illustrates a lateral super-junction structure formed using polysilicon pillars in accordance with an embodiment of the invention;

FIGS. 4A to 4C are cross-sectional views illustrating a sequential process forming a lateral super-junction using polysilicon pillars in accordance with an embodiment of the invention;

FIG. 5 illustrates a vertical super-junction structure formed using polysilicon pillars in accordance with another embodiment of the invention; and

FIGS. 6A to 6C are cross-sectional views illustrating a sequential process for forming a vertical super-junction using polysilicon pillars in accordance with another embodiment of the invention.

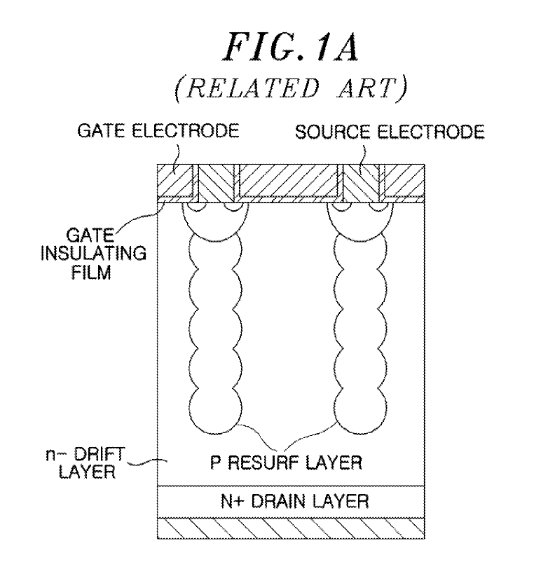

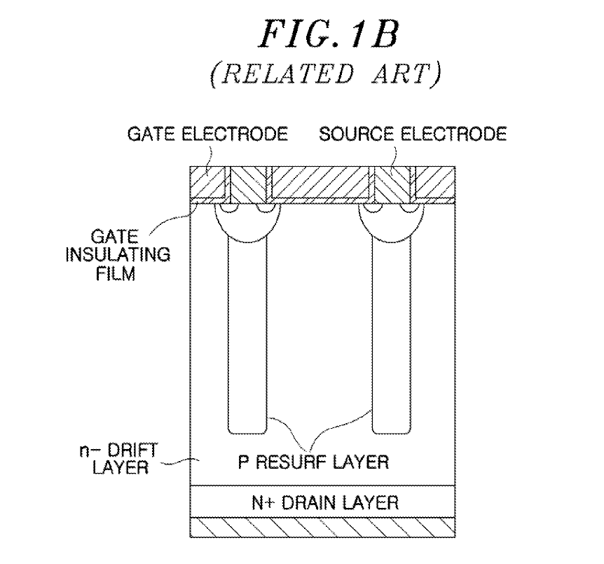

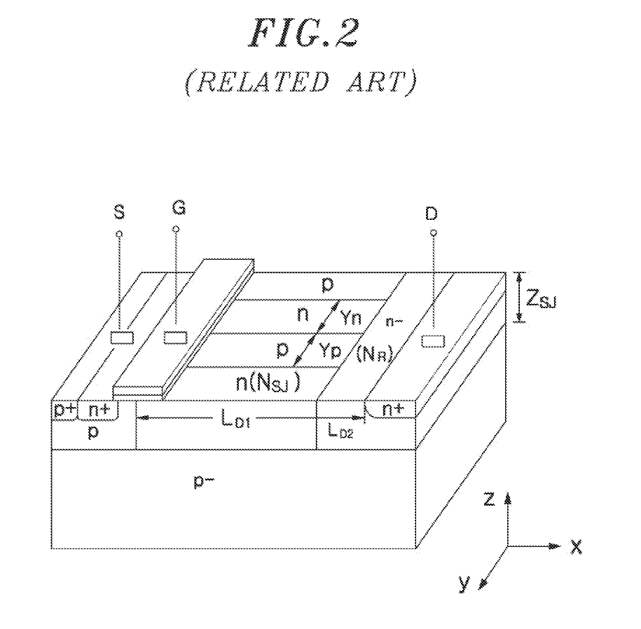

### DETAILED DESCRIPTION OF THE EMBODIMENTS

The advantages and features of the present invention and methods of accomplishing these advantages and features will be clearly understood from the following description of various embodiments taken in conjunction with the accompanying drawings. However, the present invention is not limited to the following description and intended to cover alternatives, modifications, and equivalents that may be included within the spirit and scope of the invention as defined in the appended claims. It should be noted that the present description is provided to describe and explain, but not limit, the invention.

FIG. 3 shows a lateral super-junction structure (e.g., in a high voltage device) having pillars formed of polysilicon in accordance with an embodiment of the invention.

As shown in FIG. 3, polysilicon pillars 302 may be formed on a semiconductor substrate 300 (e.g., a single-crystal silicon wafer, or a single-crystal silicon wafer with one or more layers of epitaxial silicon grown thereon) at a height corresponding to the depth of the P-type drift region (s) in the lateral super-junction structure of the related art, patterned at regions where the pillars of p-type or n-type conductivity will be formed. The polysilicon layer may be patterned accurately in the regions where the pillars 302 will be formed on the semiconductor substrate 300. Subsequently, an epitaxial layer is grown over the entire surface of the semiconductor substrate 300, resulting in the super-junction structure having a continuous PP junction formed by the polysilicon pillars 302 and the epitaxial layer.

The conductivity type of the polysilicon pillars 302 may be the opposite of the conductivity type of the semiconductor substrate 300 and the epitaxial layer. For example, in the case where the semiconductor substrate 300 is an n-type substrate, the polysilicon pillars 302 may comprise p-type polysilicon. In contrast, in the case where the semiconductor substrate 300 is a p-type substrate, the polysilicon pillars 302 may comprise n-type polysilicon. In this way, a super-junction structure has a continuous PN junction structure at the interface of the polysilicon pillars with epitaxial layer and the substrate.

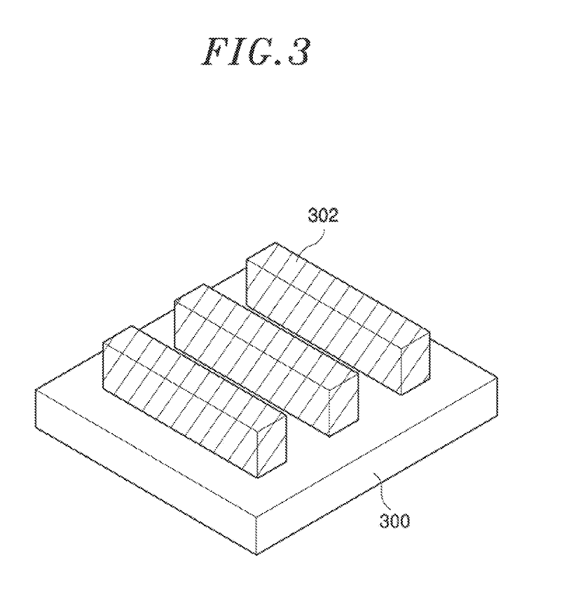

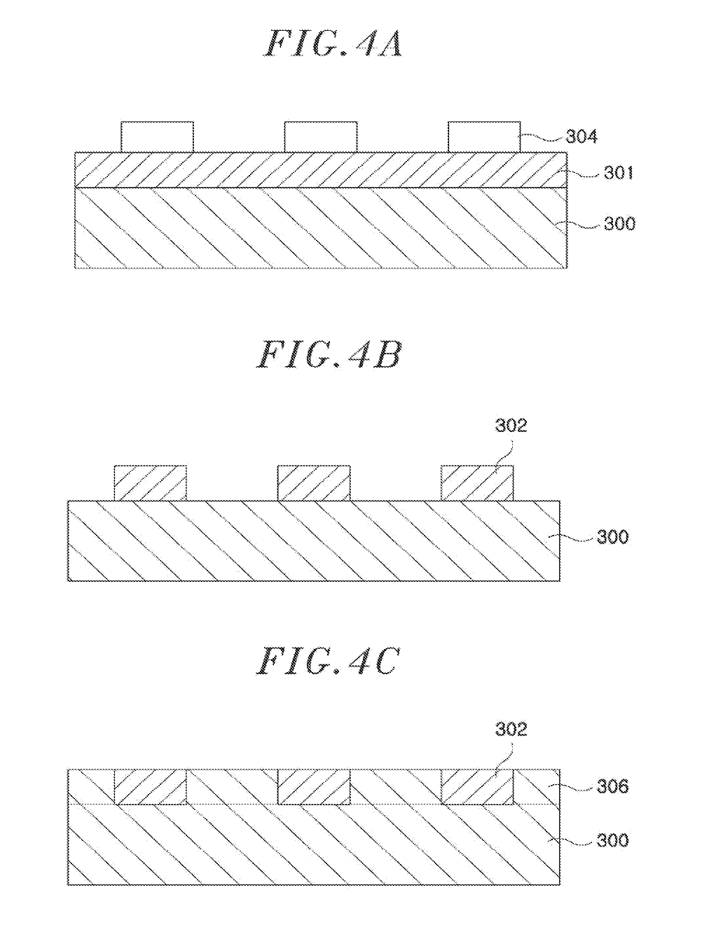

FIGS. 4A to 4C are cross-sectional views illustrating a sequential method of forming semiconductor device having a lateral super-junction structure in accordance with an embodiment of the invention. Hereinafter, the method for forming the lateral super-junction in accordance with an embodiment of the invention will be described in detail with reference to the drawings. In the following description, the method of forming the lateral super-junction on an n-type semiconductor substrate will be described, but the same general method may be applied to a super-junction structure formed on a p-type semiconductor substrate.

First, as shown in FIG. 4A, the polysilicon layer 301 may be formed (e.g., by low pressure chemical vapor deposition [LPCVD] of an Si source, such silane or dichlorosilane) on or over an n-type semiconductor substrate 300 at a thickness corresponding to the height (e.g., about 50 nm to about 3000 nm, or any value or range of values therein) of the P-type pillars to be formed from the polysilicon layer 301 in the super-junction structure. The polysilicon layer may be doped with a P-type dopant (or, when the semiconductor substrate 300 comprises a P-type substrate, with an N-type dopant) by an in situ doping process (e.g., by including a borane such as B₂H₆, B₄H₁₀, etc. as a reactant gas during the LPCVD process). Alternatively, the polysilicon layer 301 may be doped by an ion implantation process (e.g., implanting boron ions into the polysilicon layer and subsequently annealing the polysilicon layer).

Photoresist may then be coated on the polysilicon layer 301 and patterned by a photolithography process to form a photoresist mask 301 which defines regions where the P-type pillars will, be formed. In this process, the polysilicon layer 301 for forming the P-type pillars may comprise p-type polysilicon.

As shown in FIG. 4B, the polysilicon layer 301 formed on or over the semiconductor substrate 300 may be etched using the photoresist mask 304 to form the P-type pillars 302 in pre-determined regions of the semiconductor substrate 300. As a result, the pillars 302 may have a width at the interface with the semiconductor substrate 300 that is greater than the width at its uppermost horizontal surface (i.e., where the patterned photoresist 304 was located).

As shown in FIG. 45, after patterning the polysilicon layer 301 to form the P-type pillars 302 of the super-junction structure, n-type epitaxial silicon may be grown (e.g., by vapor phase deposition from an Si source, such silane or dichlorosilane, and an N-type dopant source, such as a phosphine [e.g., PH₃, etc.]) over the entire surface of the n-type semiconductor substrate 300 to form an n-type epitaxial layer 306. Alternatively, an elemental silicon layer can be deposited (but not necessarily grown epitaxially) by the same techniques. The n-type epitaxial layer 306 will operate as an N⁻ drift layer. The underlying n-type semiconductor substrate 300 may be in direct contact with the P-type pillars 302 and the N-type epitaxial layer 306, and thus be part of the continuous PN junction.

Accordingly, it is possible to efficiently form a super-junction structure without alternating ion-implantations of a p-type dopant into the pillars 302 (or polysilicon layer 301) and an n-type dopant into the epitaxial layer 306 to form a lateral super-junction structure. A lateral super-junction structure is formed while growing the n-type epitaxial layer 306 on the semiconductor substrate 300, where the epitaxial layer 306 is in direct contact with each of the P-type pillars 302. After growing the epitaxial layer 306, the excess epitaxial layer above the uppermost horizontal surface of the pillars 302 may be planarized (e.g., by blanket etchback or chemical mechanical polishing) to the level of or just below the uppermost horizontal surface of the pillars 302. Alternatively, a thin oxide film can be formed (by deposition or thermal growth) on the uppermost horizontal surface of the polysilicon layer 301 before patterning, which can prevent epitaxial growth of silicon on the uppermost horizontal surface of the pillars 302, and the oxide film can be removed after formation of the epitaxial layer 306 (optionally followed by a short planarization process, such as polishing or etchback). The present method thus reliably forms a lateral super-junction structure having a continuous PN junction formed at the interface of the P-type pillars with the N-type epitaxial layer and the N-type semiconductor substrate.

A gate insulating film and a gate electrode (not shown) may be formed on or over the epitaxial layer after epitaxial layer is formed. Additionally, source and/or drain electrodes (not shown) may be formed on or over one or more of the polysilicon pillars 302 and/or a region or surface of the semiconductor substrate 300, in accordance with conventional lateral super-junction structures.

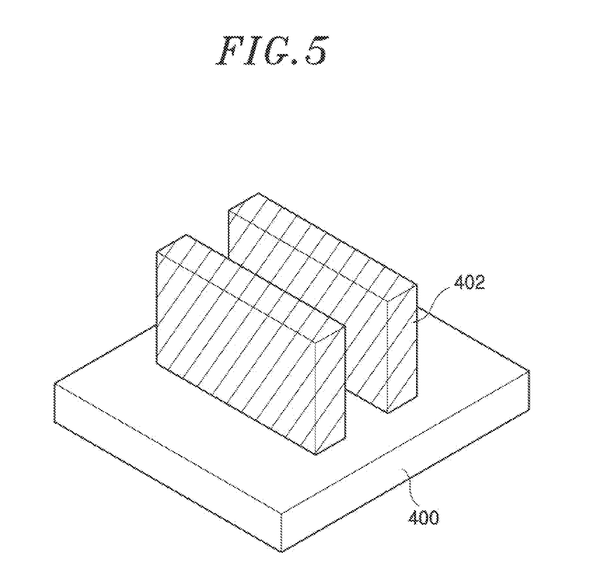

FIG. 5 shows a vertical super-junction (e.g., in a high voltage device) having pillars 402 formed from a polysilicon layer in accordance with another embodiment of the invention.

As shown in FIG. 5, polysilicon pillars 402 may be formed on or over a semiconductor substrate 400 at a height corresponding to the depth of the P+ regions in the related art vertical super-junction structure, patterned at locations where p-type or n-type pillars will be formed. The polysilicon layer may be formed and/or patterned accurately and/or reliably in the locations where the pillars 402 will be formed on the semiconductor substrate 400. Subsequently, an epitaxial layer may be grown (e.g., by vapor phase deposition of an Si source, such silane or dichlorosilane, and a dopant source, such as a phosphine) over the entire surface of the semiconductor substrate 400, resulting in the vertical super-junction structure having a continuous PN junction structure between the polysilicon pillars 402 and she epitaxial layer.

The conductivity type of the polysilicon pillars 402 may be the opposite of the conductivity type of the semiconductor substrate 400 and the epitaxial layer 406. For example, in the case where the semiconductor substrate 400 is an n-type substrate, the polysilicon pillars 402 may comprise p-type polysilicon. In contrast, in the case where the semiconductor substrate 400 is a p-type substrate, the polysilicon pillars 402 may comprise n-type polysilicon. In this way, a vertical super-junction structure having a continuous PN junction structure may be formed.

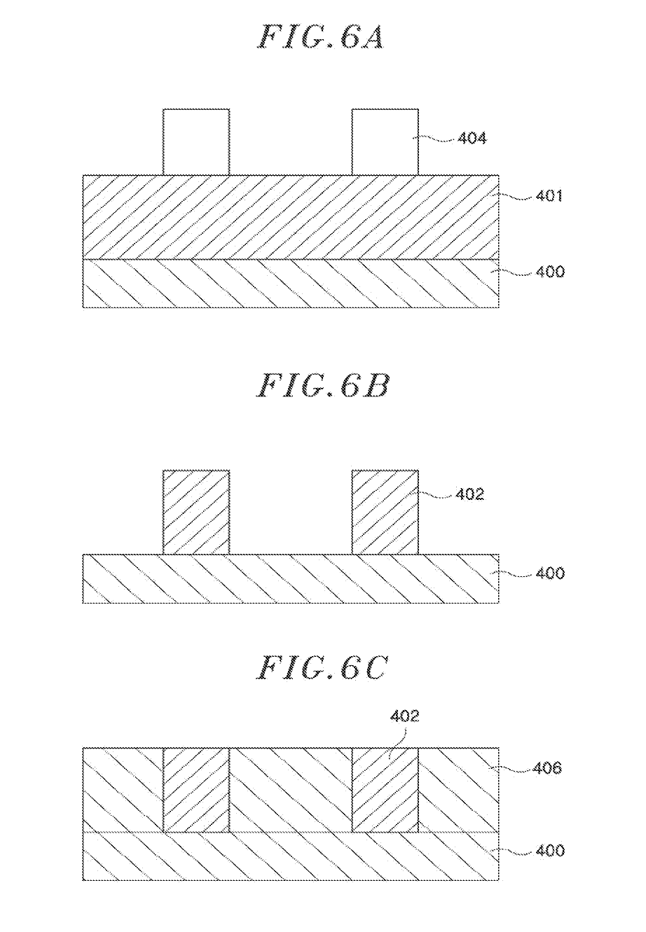

FIGS. 6A to 6C are cross-sectional views illustrating a sequential method of forming a vertical super-junction of a semiconductor device in accordance with another embodiment of the invention. Hereinafter, a process for forming a vertical super-junction will be described in detail with reference to the drawings. In the following description, a method of forming a vertical super-junction on an n-type semiconductor substrate will be described, but the same general method may be applied to a p-type semiconductor substrate.

First, as shown in FIG. 61, a polysilicon layer 401 (e.g., formed by low pressure chemical vapor deposition [LPCVD] of an Si source, such silane or dichlorosilane) may be formed on or over the n—type semiconductor substrate 400 at a thickness corresponding to the height of P-type pillars to be formed as part of the vertical super-junction structure. For example, the height of the polysilicon layer 401 may be about 1500 nm to about 5000 nm, or any value or range of values therein. The polysilicon layer may be doped with a P-type dopant (or, when the semiconductor substrate 400 is a P-type substrate, with an N-type dopant) by an in situ doping process (e g, by including B₂H₆ as a reactant gas during the LPCVD process). Alternatively, the polysilicon layer 401 may be doped by an ion implantation process (e.g., implanting boron ions into the polysilicon layer 401 and subsequently annealing the polysilicon layer 401).

Photoresist may then be coated on the polysilicon layer 401 and patterned by a photolithography process to form a photoresist mask 404 which defines regions where the P-type pillars will be formed.

The polysilicon layer 401 for the P-type pillars may be p-type polysilicon. In the vertical super junction structure, unlike the lateral super-junction structure, the drift region is formed in the vertical direction, and thus the polysilicon layer 401 is relatively higher or thicker than in the lateral super-junction structure.

As shown in FIG. 6B, the polysilicon layer 401 formed on or over the semiconductor substrate 400 other than in the regions where the P-type pillars will be formed may be etched using the photoresist mask 404 to form P-type pillars 402 in predetermined regions of the semiconductor substrate 400.

As shown in FIG. 6C, after patterning the polysilicon layer 401 to form the P-type pillars 402 of the vertical super-junction structure, n—type epitaxial silicon may be deposited or grown (e.g., as described herein) over the entire surface of the n-type semiconductor substrate 400 to form an n-type epitaxial layer 406 that will operate as an N⁻ drift layer.

Accordingly, it is possible to simply and efficiently form a vertical super-junction structure without alternating ion-implantations of a p-type dopant into the P-type regions or layers and an n—type dopant into the n-type regions or layers. In addition, the vertical super-junction structure is formed in the course of growing the epitaxial layer 406 on the semiconductor substrate 400. The resulting structure has a continuous PN junction at the interface of the P-type pillars 402 and the N-type epitaxial layer 406 (and, optionally, the N-type semiconductor substrate 400). The present method thus makes it possible to more accurately and/or reliably form a vertical super-junction structure having a continuous PN junction.

A gate insulating film (not shown), a gate electrode (not shown), and source and drains electrodes and/or contacts (not shown) may be formed on or over the epitaxial layer 406, the polysilicon pillars 402 and/or the semiconductor substrate 400 in accordance with conventional vertical super-junction structures.

As described above, an n-type or p-type polysilicon layer may be formed at a desired height on a semiconductor substrate and then patterned to form polysilicon pillars of a super-junction, and an epitaxial layer may be grown to at least the same height as the polysilicon pillars on the semiconductor substrate to form a continuous PN junction structure between the polysilicon pillars and the epitaxial layer, thereby making a super-junction structure. It is also possible to simplify a method for forming a super-junction without using a repetitive ion implantation process or a trench process in the related art, resulting in increasing productivity and device reliability.

While the description is directed toward embodiments of the present invention, the present invention is not limited to the embodiments described herein. It will be understood by those skilled in the art that various changes, equivalents, and modifications may be made without departing from the scope of the invention as defined in the following claims.

What is claimed is:

1. A method of forming a super-junction in a semiconductor device, the method comprising:
forming a polysilicon layer on or over a semiconductor substrate;
patterning the polysilicon layer to form polysilicon pillars on or over the semiconductor substrate; and
growing an epitaxial layer on the semiconductor substrate to at least a height equal to a height of the polysilicon pillars, wherein a continuous PN junction is formed at an interface of the polysilicon pillars and the epitaxial layer.

2. The method of claim 1, wherein the polysilicon layer has a height corresponding to the height of the polysilicon pillars.

3. The method of claim wherein the polysilicon pillars have a first conductivity type opposite to a second conductivity type of the semiconductor substrate.

4. The method of claim 3, wherein the epitaxial layer and the semiconductor substrate have the second conductivity type.

5. The method of claim 4, further comprising introducing a dopant having the first conductivity type into the polysilicon layer, and introducing a dopant having the second conductivity type into the epitaxial layer.

6. The method of claim 1, wherein the epitaxial layer and the semiconductor substrate are N-type and the polysilicon pillars are P-type.

7. The method of claim 1, further comprising planarizing the epitaxial layer until the epitaxial layer and the polysilicon pillars have a substantially coplanar uppermost surface.

8. The method of claim 1, wherein the height of the polysilicon pillars is about 50 nm to about 500 nm.

9. The method of claim 1, wherein the height of the polysilicon pillars is about 500 nm to about 3000 nm.

10. The method of claim 1, wherein the height of the polysilicon pillars is about 1500 nm to about 5000 nm.

11. The method of claim 1, wherein the one or more polysilicon pillars and the epitaxial layer are in direct contact with the substrate.

12. A super-junction structure of a semiconductor device comprising:
polysilicon pillars on or over a semiconductor substrate;
an epitaxial layer between the polysilicon pillars and on or over the semiconductor substrate to form a continuous PN junction at an interface of the polysilicon pillars with the epitaxial layer.

13. The super-junction structure of claim 12, wherein the height of the polysilicon pillars is about 1500 nm to about 5000 nm, and the epitaxial layer has a height a height equal to the a height of the polysilicon pillars.

14. The super-junction structure of claim 12, wherein the height of the polysilicon pillars is about 500 nm to about 3000 nm, and the epitaxial layer has a height a height equal to the a height of the polysilicon pillars.

15. The super-junction structure of claim 12, wherein the polysilicon pillars have a first conductivity type opposite to a second conductivity type of the semiconductor substrate.

16. The super-junction structure of claim 12, wherein the epitaxial layer has a same conductivity type as the conductivity type of the semiconductor substrate.

17. The super-junction structure of claim 15, wherein the epitaxial layer has the second conductivity type.

18. The super-junction structure of claim 12, wherein the polysilicon pillars and the epitaxial layer have, a substantially coplanar uppermost surface.

19. The super-junction structure of claim 12, wherein the polysilicon pillars and the epitaxial layer are in direct contact with the substrate.

20. The super-junction structure of claim 18, wherein the polysilicon pillars have a first width at an interface with the semiconductor substrate that is greater than a second width at the uppermost surface.
